(19) United States
(12) Patent Application Publication
(10) Pub. No.: US 2025/0044359 A1
(43) Pub. Date: Feb. 6, 2025

(54) BATTERY STATE-OF-HEALTH PREDICTION

(71) Applicant: Toyota Motor Engineering & Manufacturing North America, Inc., Plano, TX (US)

(72) Inventors: Siwen Wang, Ann Arbor, MI (US); Chen Ling, Troy, MI (US)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 18/365,719

(22) Filed: Aug. 4, 2023

(51) Int. Cl. G01R 31/367; G01R 31/392; G06N 5/022; G06N 20/00

(52) U.S. Cl. CPC G01R 31/367; G01R 31/392; G06N 5/022; G06N 20/00

(57) ABSTRACT

A system for determining a future state-of-health (SOH) of a battery includes a memory communicably coupled to a processor and storing instructions that, when executed by the processor, cause the processor to acquire battery data of a battery for which a future SOH is to be predicted. The instructions also cause the processor to identify a selected model from an ensemble of models according to at least a time to the future SOH and a time length of the battery data. The instructions further cause the processor to predict the future SOH using the battery data as an input to the selected model.

### TECHNICAL FIELD

The subject matter described herein relates, in general, to predicting a state-of-health (SOH) of a battery at a future time and, more particularly, to predicting a SOH of a battery using an ensemble of machine learning models.

### BACKGROUND

As popularity in electric vehicles (EVs) rises, the burden to replace faulty batteries will rapidly increase. Moreover, current regulations require original equipment manufacturers (OEMs) to provide accurate information to their customers about the state of their batteries, including information about the state-of-health (SOH) of the batteries. Accordingly, systems and methods to evaluate the state of batteries are widely used, and accuracy of such systems and methods is very important. Traditional systems and methods used to evaluate the state of batteries often rely on electrochemical lab measurements, which are not only expensive and time-consuming to collect, but also performed only in qualified labs. In recent years, digital modeling and simulating of battery states have improved, as such methods either simplify the battery in an equivalent circuit or consider more complex reaction and mass transportation within batteries. Such methods, however, still rely on the knowledge of the physical condition of each battery, for example, the resistance and impedance, which is costly to measure in a lab.

### SUMMARY

In one embodiment, example systems and methods relate to predicting a future state-of-health SOH of a battery. In one approach, a prediction module employs a multi-part process for predicting a future SOH of a battery.

In a first part, in one approach, a prediction module trains a machine learning-based estimation model to predict current SOH values of batteries using lab-measured SOH values. The estimation model permits generating historical SOH data for the batteries so that time consuming, expensive lab measurements of the SOH values do not have to be collected. To train the estimation model, in one example, the prediction module uses battery data of the batteries at the same time point as the lab measurements as the training data for the estimation model. Additionally, in one approach, the prediction module uses the lab-measured SOH values as a supervising signal for the estimation model to generate a loss value according to corresponding predictions and update the estimation model.

In a second part, in one approach, the prediction module applies the estimation model to the battery data, which includes, in one example, data from the production date of the batter until the current moment, in order to acquire the historical SOH data. The prediction module uses the historical SOH data later as training data to train an ensemble of machine-learning models used to predict a future SOH of a new battery. In one approach, the prediction module then constructs a SOH history curve using the historical SOH data and acquires a mileage curve, which is a curve of the mileage of respective vehicles associated with the batteries as a function of time. In one approach, the prediction module filters the historical SOH data to ensure the historical SOH data is suitable for use as the training data for the ensemble of models. In one example, filtering the historical SOH data includes identifying outlying data points on the SOH history curve, as well as cross-checking the historical SOH data with the mileage curve to identify significant changes in use of the battery that might affect the smoothness of the historical SOH data.

In one approach, as mentioned above, the prediction module then uses the filtered historical SOH data as training data for the ensemble of models, which are then used to predict future SOH values according to battery data. In one example, the prediction module characterizes the historical SOH data as either early time sequency data or as late time sequency data. In one approach, the battery data corresponding to the early time sequency data is used as training data for each model in the ensemble of models, and the late time sequency data is used as the supervising signal for each model in the ensemble of models to generate a loss value for each model and update each model. For at least some of the models, in one approach, the prediction module characterizes the historical SOH data differently with respect to the SOH history curve in order to obtain an ensemble of differently-trained models, which may be advantageous to account for variations in the data of the new battery for which the prediction module will predict a future SOH. In other words, in one example, the early time sequency data and the late time sequency data for each model are located at different time points of the SOH history curve.

In a third part, in one approach, the prediction module generates a prediction error for each model in the ensemble. In one example, the prediction error is a measurement of the accuracy of each model based on various prediction criteria, including the time length of the battery data and the time to the future SOH prediction. Based on the prediction error, in one approach, the prediction module creates an assignment of each model to the prediction criteria in order to determine the most accurate model for the prediction criteria of a new battery. In one approach, the prediction module then identifies a selected model for the new battery based on the assignment and uses new battery data as the input to the selected model to predict a future SOH for the new battery.

According to the systems and methods described herein, the ability to accurately predict the SOH of batteries at future times will provide additional avenues to create more valuable products such as better warranty and insurance policies, enable secondary usage of batteries, and help prevent life-threatening accidents due to battery failure. Accordingly, the systems and methods described herein provide cost-friendly and accurate predictions of the future SOH of a battery without electrochemical lab testing of the battery itself. The systems and methods described herein have the benefit of evaluating the battery individually and independently of other batteries to avoid errors caused by averaging the behavior of a group of batteries, as well as using data collected during driving of the vehicle containing the battery in order to consider the environmental effects on the battery SOH to provide a more accurate SOH prediction.

In one embodiment, a system includes a memory communicably coupled to a processor and storing instructions that, when executed by the processor, cause the processor to acquire battery data of a battery for which a future state-of-health (SOH) is to be predicted. The instructions also cause the processor to identify a selected model from an ensemble of models according to at least a time to the future SOH and a time length of the battery data. The instructions further cause the processor to predict the future SOH using the battery data as an input to the selected model.

In another embodiment, a non-transitory computer-readable medium includes instructions that, when executed by one or more processors, cause the one or more processors to acquire battery data of a battery for which a future state-of-health (SOH) is to be predicted. The instructions also cause the one more processors to identify a selected model from an ensemble of models according to at least a time to the future SOH and a time length of the battery data. The instructions further cause the one or more processors to predict the future SOH using the battery data as an input to the selected model.

In yet another embodiment, a method includes acquiring battery data of a battery for which a future state-of-health (SOH) is to be predicted. The method also includes identifying a selected model from an ensemble of models according to at least a time to the future SOH and a time length of the battery data. The method further includes predicting the future SOH using the battery data as an input to the selected model.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements, or multiple elements may be designed as one element. In some embodiments, an element shown as an internal component of another element may be implemented as an external component and vice versa. Furthermore, elements may not be drawn to scale.

FIG. 1. illustrates one example of a prediction system associated with predicting a future state-of-health (SOH) of a battery.

FIG. 2 illustrates a flowchart of one example of a multi-part method of predicting a future SOH of a battery.

FIG. 3A illustrates a flowchart of one example of a method associated with training an estimation model in a first part of the method of FIG. 2.

FIG. 3B illustrates various examples of data used and output in the first part of the method of FIG. 2.

FIG. 4A illustrates a flowchart of one example of a method associated with training an ensemble of models in a second part of the method of FIG. 2.

FIG. 4B illustrates various examples of data used and output in the second part of the method of FIG. 2.

FIG. 5A illustrates a flowchart of one example of a method of predicting a future SOH of a battery in a third part of the method of FIG. 2.

FIG. 5B illustrates one example of a prediction error of the ensemble of models used in the third part of the method of FIG. 2.

FIG. 5C illustrates one example of an assignment of each model in the ensemble to various criteria of a future SOH prediction.

### DETAILED DESCRIPTION OF THE DRAWINGS

Systems, methods, and other embodiments associated with predicting a future state-of-health (SOH) of a battery are disclosed. In a first part, in one approach, a prediction module of a prediction system for predicting a future SOH of a battery trains an estimation model to predict current SOH values of batteries using lab-measured SOH values of the batteries. Using the estimation model, the prediction module generates historical SOH data for the batteries. The prediction module, in one example, trains the estimation model using battery data as the training data for the estimation model. The prediction module, in one approach, also uses the lab-measured data as a supervising signal for the estimation model.

In one approach of a second part, the prediction module applies the estimation model to the battery data to generate historical SOH data for later use as training data for an ensemble of machine-learning models used to predict a future SOH of a new battery. In one approach, using the historical SOH data, the prediction module constructs a SOH history curve and acquires a mileage curve of the mileage of the batteries as a function of time. In one approach, the prediction module filters the historical SOH data before use as the training data for the ensemble of models. The prediction module, in one approach, then uses the filtered historical SOH data as training data for each model in the ensemble. Before use as the training data, in one example, the prediction module characterizes the historical SOH data as either early time sequency data or as late time sequency data. In one approach, the battery data corresponding to the early time sequency data is used as training data for each model in the ensemble of models, and the late time sequency data is used as the supervising signal for each model in the ensemble of models to generate a loss value for each model and update each model. In one approach, the prediction module characterizes the historical SOH data differently for each model in the ensemble. In other words, in one example, the early time sequency data and the late time sequency data for each model are located at different time points of the SOH history curve.

In one approach of a third part, for each model, the prediction module generates a prediction error, which in one example is a measurement of the accuracy of each model based on various prediction criteria. In one approach, the prediction criteria include the time length of the battery data and the time to the future SOH prediction. Based on the prediction error, in one approach, the prediction module creates an assignment of each model to the prediction criteria in order to determine the most accurate model for the prediction criteria of a new battery. In one approach, the prediction module then identifies a selected model for the new battery based on the assignment and uses new battery data as the input to the selected model to predict a future SOH for the new battery.

The systems and methods described herein provide the ability to accurately predict the SOH of a battery at a future time. Accurate future SOH predictions of batteries may lead to the creation of better warranty and insurance policies, enable secondary usage of batteries, and help prevent accidents due to battery failure. The systems and methods described herein also provide cost-friendly predictions of the future SOH of a battery without expensive lab testing of the battery itself. The systems and methods described herein further have the benefit of evaluating the battery individually and independently of other batteries to avoid errors caused by averaging the behavior of a group of batteries, as well as using data collected during driving of the vehicle containing the battery in order to consider the environmental effects on the battery SOH to provide a more accurate SOH prediction.

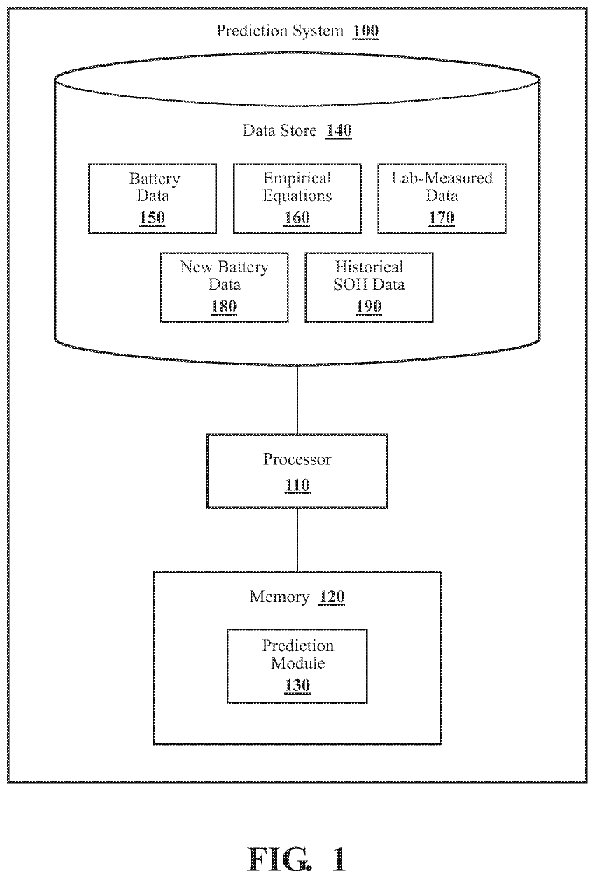

Referring now to FIG. 1, one example of a prediction system is shown. While depicted as a standalone component, in one or more embodiments, the prediction system is cloud-based and thus can include elements that are distributed among different locations. In general, the prediction system is implemented to acquire information from the various locations to support the functions discussed herein. That is, in at least one approach, the prediction system functions to acquire information from the various locations. The noted functions and methods will become more apparent with a further discussion of the figures.

With further reference to FIG. 1, one embodiment of the prediction system 100 is further illustrated. The prediction system 100 is shown as including a processor 110. Accordingly, the processor 110 may be a part of the prediction system 100, or the prediction system 100 may access the processor 110 through a data bus or another communication path. In one or more embodiments, the processor 110 is an application-specific integrated circuit (ASIC) that is configured to implement functions associated with a prediction module 130. In general, the processor 110 is an electronic processor, such as a microprocessor that is capable of performing various functions as described herein. In one embodiment, the prediction system 100 includes a memory 120 that stores a prediction module 130. The memory 120 is a random-access memory (RAM), read-only memory (ROM), a hard disk drive, a flash memory, or other suitable memory for storing the prediction module 130. The prediction module 130 is, for example, computer-readable instructions that, when executed by the processor 110, cause the processor 110 to perform the various functions disclosed herein. In further arrangements, the prediction module 130 is a logic, integrated circuit, or another device for performing the noted functions that includes the instructions integrated therein.

Furthermore, the prediction system 100 includes a data store 140. The data store 140 is, in one arrangement, an electronic data structure stored in the memory 120 or another electronic medium, and that is configured with routines that can be executed by the processor 110 for analyzing stored data, providing stored data, organizing stored data, and so on. Thus, in one embodiment, the data store 140 stores data used by the prediction module 130 in executing various functions. For example, as depicted in FIG. 1, the data store 140 includes battery data 150, empirical equations 160, lab-measured data 170, new battery driving data 180, and historical SOH data 190, along with, for example, other information that is used and/or produced by the prediction module 130. Each of the aforementioned elements will be described in further detail below. While the prediction system 100 is illustrated as including the various elements, it should be appreciated that one or more of the illustrated elements may not be included within the data store 140 in various implementations. In any case, the prediction system 100 stores various data elements in the data store 140 to support functions of the prediction module 130.

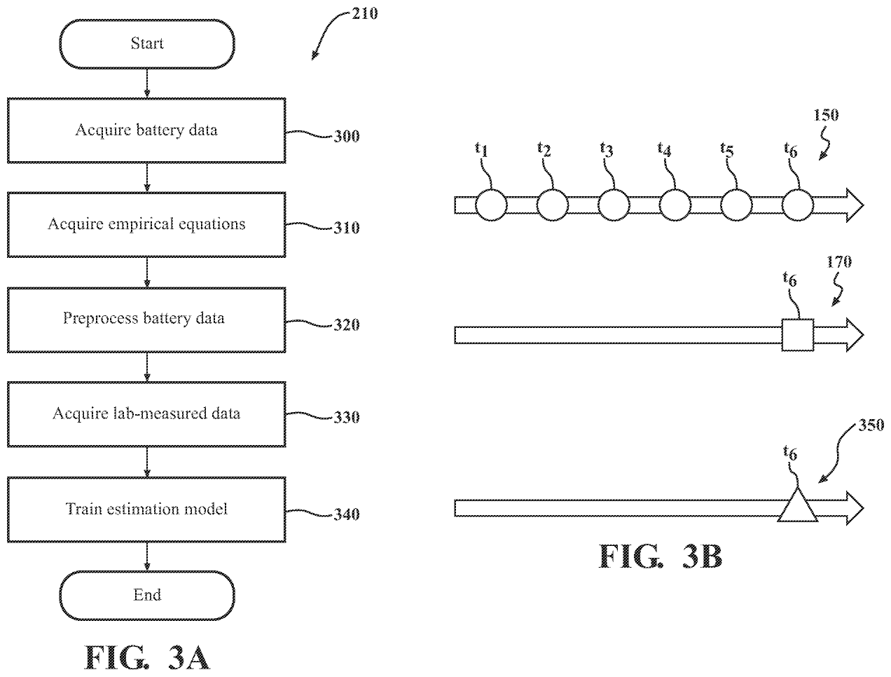

Continuing with the elements shown in the data store 140, the battery data 150 includes, for example, data regarding the batteries of EVs during the driving and resting of the EVs. As described in further detail below, in one approach, the processor 110 uses the battery data 150 as the training data for an estimation model. As described in further detail below, the prediction module 130 trains the estimation model to estimate a SOH for each battery using the battery data 150. The battery data 150 includes data of a number of batteries of EVs. For example, the battery data 150 includes data of around 10,000 batteries. The battery data 150 includes data collected over a data collection time period. For example, the battery data 150 includes data collected over a time period of about 6 months, about 1 year, about 10 years, or another length of time. The battery data 150 includes data collected during the data collection time period at a frequency with enough data to characterize the behavior of each battery. For example, the battery data 150 includes data collected during the data collection time period at a frequency of about once a month. The batteries include a type of battery used in a type of EV, for example, electric passenger vehicles and SUVs. In one approach, the processor 110 receives the battery data 150 from the battery management systems (BMSs) of the EVs corresponding to the batteries. One example of the battery data 150 will be described in further detail below in connection with FIGS. 3A and 3B.

In one approach, after receiving the battery data 150, the processor 110 preprocesses the battery data 150 in a preprocessing phase before use as the training data for the estimation model. In some instances, the preprocessing phase helps ensure greater accuracy of the estimation model. The preprocessing phase includes, in some instances, filtering the battery data 150 to obtain the most relevant features of the battery data 150 for use as the training data for the estimation model. The most relevant features include, for example, relevant battery features and relevant vehicle features at each time point. The relevant battery features include, for example, the battery temperature, battery charge and discharge information, the battery current, the battery charging capacity, the battery resistance, etc. The relevant vehicle features include, for example, the vehicle mileage, the vehicle running distance, the vehicle ignition status (vehicle ignition on or vehicle ignition off), etc. In some instances, the preprocessing phase also includes applying empirical equations 160 to the battery data 150 to account for the physics and/or physical characteristics of the battery. As mentioned above, the data store 140 includes empirical equations 160 relating to the physics of the battery. In one approach, the processor 110 applies the empirical equations 160 to the battery data 150 before using the battery data 150 as the training data for the estimation model.

It should be understood that the depiction of each time point in FIG. 3B may represent multiple data points. For example, each of the time points depicted in FIG. 3B may represent the individual data points for each relevant battery feature and each relevant vehicle feature for each battery. For example, if there are 10 relevant battery features, 10 relevant vehicle features, and 10,000 batteries, the depiction of each time point for the battery data 150 may represent 200,000 data points. More specifically, in this example, each of t₁ through to corresponds to 200,000 data points.

In one approach, in conjunction with the collection of the battery data 150, the batteries are also electrochemically tested in a lab to determine the true SOH of each battery. In some instances, the true SOH is the true SOH at the time point when the lab testing occurs. Accordingly, as mentioned above, the data store 140 also includes lab-measured data 170 regarding the batteries. The lab-measured data 170 may be obtained by a method involving the electrochemical testing of the individual cells in each battery. The SOH of each battery is thus an accumulation of the SOH measurements of each individual cell. FIG. 3B depicts the lab-measured data 170 in a similar pictorial manner as the battery data 150. In one example, as shown in FIG. 3B, the lab-measured data 170 is collected at t₆, corresponding to the last time point in the battery data 150. However, it should be understood that the lab-measured data 170, in other examples, can be collected at another time point. Moreover, while the lab-measured data 170 is only collected in some examples at one time point to reduce high costs associated with lab testing of batteries, it should be understood that in other examples, the lab-measured data 170 may be collected at two or more time points. As described in further detail below, the lab-measured data 170 is used as a supervising signal for the estimation model to generate a loss value for the estimation model and update the estimation model.

It should be understood that the depiction of the lab-measured data 170 time point may represent multiple data points. For example, the lab-measured data 170 time point represents each of the lab-measured, true SOH values of each battery that is electrochemically tested. For example, if there are 10,000 EVs, the lab-measured data 170 time point represents 10,000 true SOH values. More specifically, in this example, t₆ represents 10,000 true SOH values.

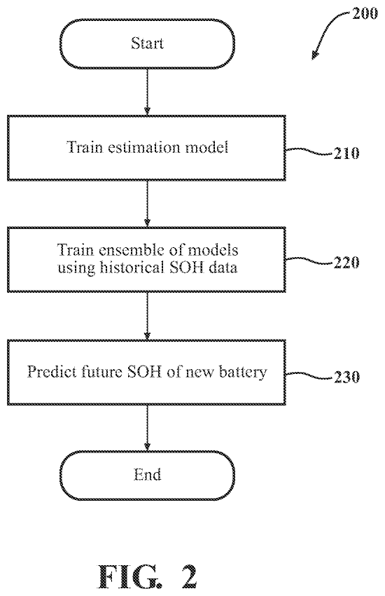

As mentioned above, the data store 140 includes new battery data 180, which includes battery data of a new battery not of which the prediction module 130 will predict a future SOH. In one approach, the processor 110 receives the new battery data 180 from the BMS of the vehicle associated with the new battery and includes data regarding the new battery during driving and resting of the vehicle. In some instances, the new battery data 180 includes similar relevant features described above in connection with the battery data 150, and, in some instances, the new battery data 180 is preprocessed in a similar manner to the battery data 150. Accordingly, in some arrangements, the new battery data 180 includes the most relevant new battery data 180 features, for example, relevant new battery features and relevant new vehicle features. The relevant new battery features include, for example, the battery temperature, battery charge and discharge information, the battery current, the battery charging capacity, the battery resistance, etc. The relevant new vehicle features include, for example, the vehicle mileage, the vehicle running distance, the vehicle ignition status (vehicle ignition on or vehicle ignition off), etc. As described in further detail below with reference to FIGS. 2-5C, the prediction module 130 uses the new battery data 180 to predict a future SOH of the new battery.

As mentioned above, the data store 140 also includes historical SOH data 190. The historical SOH data 190 includes historical SOH estimates for each time period of the battery data 150. In one example, and as described in further detail below, the prediction module 130 generates the historical SOH data 190 in a second part of a method for predicting a future SOH of a vehicle battery.

Referring now to FIG. 2, FIG. 2 illustrates a flowchart of a method 200 for predicting a future SOH of the new battery. The method 200 will be discussed from the perspective of the prediction system 100 of FIG. 1. While the method 200 is discussed in combination with the prediction system 100, it should be appreciated that the method 200 is not limited to being implemented within the prediction system 100 but is instead the prediction system 100 is one example of a system that may implement the method 200. Moreover, the method 200 is an overview of one example of a broader method that includes separate methods to perform the functions associated with the separate blocks of the method 200. The separate methods may function independently of each other or may function together as one overall method.

At 210, the prediction module 130 builds the estimation model using the battery data 150 as training data and the lab-measured data 170 as the supervising signal. At 220, the prediction module 130 applies the estimation model to the battery data 150 to obtain the historical SOH data 190, which the prediction module 130 uses to train an ensemble of models. At 230, the prediction module 130 selects the best model from the ensemble for the prediction of a future SOH of the new battery, and the prediction module 130 uses the selected model to predict the future SOH of the new battery. Each of the parts of the method will be described in further detail below with additional reference to FIGS. 3-5A.

Referring now to the first part 210 of the method 200, FIG. 3 illustrates an example flowchart of 210. At 300, the prediction module 130 acquires the battery data 150. In one approach, the prediction module 130 receives the battery data 150 through active acquisition (i.e., controlling a device to acquire the battery data 150). For example, the prediction module 130 controls the processor 110 to acquire the battery data 150 from the data store 140. In another approach, the prediction module 130 acquires the battery data 150 through communication of the battery data 150 via a data communication link. For example, the processor 110 initiates communication of the battery data 150 from the data store 140 to the prediction module 130.

At 310, the SOH prediction module 130 acquires the empirical equations 160. In one approach, the prediction module 130 receives the empirical equations 160 through active acquisition (i.e., controlling a device to acquire the empirical equations 160). For example, the prediction module 130 controls the processor 110 to acquire the empirical equations 160 from the data store 140. In another approach, the prediction module 130 acquires the empirical equations 160 through communication of the empirical equations 160 via a data communication link. For example, the processor 110 initiates communication of the empirical equations 160 from the data store 140 to the prediction module 130.

At 320, the prediction module 130 preprocesses the battery data 150. As described above, the prediction module 130 preprocesses the battery data 150 by filtering out the relevant battery features and/or relevant vehicle features at each time point and/or applying the empirical equations 160 to the battery data 150. The most relevant features include, for example, the battery temperature, battery charge and discharge information, the battery current, the battery charging capacity, the battery resistance, the vehicle mileage, the vehicle running distance, the vehicle ignition status (vehicle ignition on or vehicle ignition off), etc. In one approach, the prediction module 130 applies the empirical equations 160 to the battery data 150 before using the battery data 150 as the training data for the estimation model.

At 330, the prediction module 130 acquires the lab-measured data 170. In one approach, the prediction module 130 receives the lab-measured data 170 through active acquisition (i.e., controlling a device to acquire the lab-measured data 170). For example, the prediction module 130 controls the processor 110 to acquire the lab-measured data 170 from the data store 140. In another approach, the prediction module 130 acquires the lab-measured data 170 through communication of the lab-measured data 170 via a data communication link. For example, the processor 110 initiates communication of the lab-measured data 170 from the data store 140 to the prediction module 130.

At 340, as described in further detail below, the prediction module 130 trains the estimation model to estimate a SOH for each battery based on the battery data 150. In one approach, training the estimation model includes providing input data, which includes, for example, the preprocessed battery data 150, and executing the estimation model to train the estimation model to estimate a SOH for each battery. Training the estimation model also includes, in one approach, receiving output data, which includes, for example, estimated SOH values for each battery, and comparing the output data to ground truth data to generate a loss value. In one approach, the ground truth data is the lab-measured data 170, and the prediction module uses the loss value to backpropagate the loss through the estimation model to update each iteration of the estimation model.

In one approach, as mentioned above, to train the estimation model, in one example, the prediction module 130 uses the preprocessed battery data 150 as the input data to the estimation model. FIG. 3B illustrates one example of the battery data 150 pictorially. As shown, the battery data 150, represented by circles, includes data regarding the batteries of each EV at a number of time points. In this example, the battery data 150 includes BMS data of each EV at 6 time points (t₁, t₂, t₃, t₄, t₅, and t₆) corresponding to the collection of data once a month for six months. More specifically, the battery data 150 includes BMS data collected for each EV in a first month (t₁), BMS data collected for each EV in a second month (t₂), BMS data collected for each EV in a third month (t₃), BMS data collected for each EV in a fourth month (t₄), BMS data collected for each EV in a fifth month (t₅), and BMS data collected for each EV in a sixth month (t₆). In one approach, the six months occur one after the other (for example, the six months are January, February, March, April, May, and June), and in another approach, two or more of the six months may be separated by one or more other months (for example, the six months are January, March, May, July, September, and November). While the battery data 150 is shown in FIG. 3B as including data collected once a month for six months, this is intended to be merely one example of the battery data 150. In other examples, the battery data 150 includes data collected at another frequency, and thus includes another number of time points.

To train the estimation model, in one approach, the prediction module 130 uses, as the input data, the battery data 150 corresponding to the time point at which the lab-measured data 170 was collected as the training data. For example, as illustrated in FIG. 3B, the prediction module 130 uses the battery data 150 at t₆ as the training data. The prediction module 130 uses the lab-measured data 170, depicted as a square in FIG. 3B, corresponding to the time point of the battery data 150 as the supervising signal. For example, as illustrated in FIG. 3B, the prediction module 130 uses the lab-measured data 170 at t₆ as the supervising signal, i.e., ground truth for determining the accuracy of the output. Thus, the prediction module 130 trains the estimation model to estimate the SOH of each battery at the time point corresponding to the battery data 150 and the lab-measured data 170. For example, as shown in FIG. 3B, an output 350 of the estimation model is the estimated SOH, depicted as a triangle, of each battery at t₆. The prediction module 130 executes the estimation model over the battery data 150, and the output 350 of the estimation model is a SOH estimation that is compared against the lab-measured data 170 to derive a loss value which is used to update the estimation model. Thus, the lab-measured data 170 is supervised, annotated data used to train the estimation model. Accordingly, in one embodiment, the estimation model is a supervised model, and the output 350 of the model is compared to the lab-measured data 170 to improve the training of the estimation model. As described in further detail below, the estimation model can be used to predict a current SOH of the battery (e.g., the output 350) based on the current battery properties. Thus, the estimation model is a 1-to-1 model. As used herein the term “1-to-1” indicates that the output 350 is a same-day SOH estimation, meaning that the output 350 is the estimated SOH at the same day of the battery data 150 and the lab-measured data 170.

In the arrangements described herein, the estimation model is a Least Absolute Shrinkage and Selection Operator (LASSO) regression. However, it should be understood that the estimation model can be another type of model, for example, an Artificial Neural Network (ANN), a reinforcement learning model, a deep learning model, a support vector machine, a logistic regression, a linear regression, a random forest, etc. Moreover, while the estimation model is described herein as a supervised machine-learning model, it should be understood that in one or more other approaches, the estimation model can be an unsupervised machine-learning model or a reinforced machine-learning model.

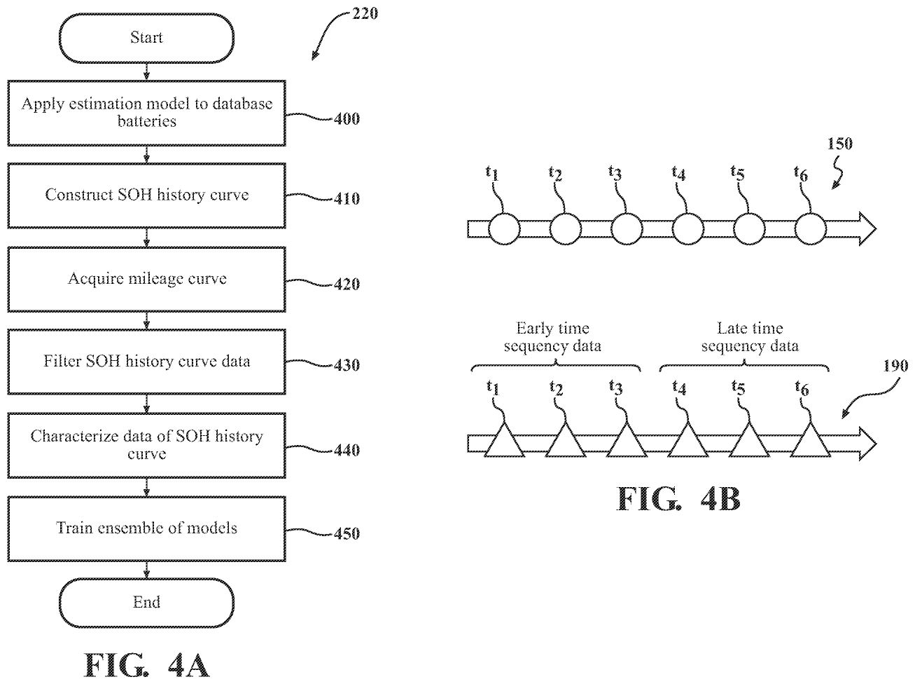

Referring now to the second part 220 of the method 200, FIG. 4A illustrates an example flowchart of 220. At 400, the prediction module 130 applies the estimation model to the battery data 150, depicted as circles, to obtain the historical SOH data 190 for each battery. Accordingly, the prediction module 130 applies the estimation model to each time point in the battery data 150 to obtain historical SOH data 190, depicted as triangles, for each battery at each time point. For example, the prediction module 130 applies the estimation model to the t₁, t₂, t₃, t₄, t₅, and t₆ time points in the battery data 150 to obtain historical SOH data 190 for each of the time points t₁, t₂, t₃, t₄, and t₅, and t₆. One of the advantages of using the estimation model in 220 to generate the historical SOH data 190 is that the batteries do not have to be lab-tested at each time point to obtain the historical SOH data 190. As described above, generating the historical SOH data 190 using the estimation model helps avoid expensive, time-consuming lab testing of the batteries.

At 410, the SOH prediction module 130 uses the historical SOH data 190 to construct a SOH history curve for the batteries. The SOH history curve is a curve of the SOH of each battery as a function of time (for example, the number of days since the production of the EV associated with the battery). At 420, the SOH prediction module 130 acquires a milage curve. In one embodiment, the processor 110 constructs a mileage curve using the battery data 150. In one example, the mileage curve is a curve of the milage of each battery as a function of time (for example, the number of days since the production of the EV associated with the battery).

At 430, the SOH prediction module 130 filters the historical SOH data 190 using the SOH history curve and/or the mileage curve to identify batteries having a smooth SOH history curve and/or a smooth mileage curve to identify constantly behaved EVs. As used herein, a “smooth” curve means that there are sufficient recorded data points in the curve such that the curve looks smooth and continuous and that there are no significantly outlying data points. As such, the data filtering phase of 430 is important because in some arrangements it helps improve the accuracy of the ensemble of models when trained using the historical SOH data 190, as will be described in further detail below. In one approach, filtering the historical SOH data 190 includes removing significantly outlying data points on the SOH history curve. Additionally, in one approach, filtering the historical SOH data 190 includes filtering out data from batteries having a mileage curve that is not sufficiently smooth. For example, filtering the historical SOH data 190 may involve filtering out data from batteries for which the mileage curve indicates there was a significant change in driving habits or driving location of the vehicle associated with the batteries. For example, filtering the historical SOH data 190 may involve filtering out data regarding an EV that was driven around 20 miles a day for a few years and then driven about 50 miles a day for a few years after. As mentioned above, the data filtering phase ensures the quality of the training data used to train the ensemble of models.

At 440, the prediction module 130 characterizes the filtered historical SOH data 190 as early time sequency data or late time sequency data. In one approach, as described in further detail below, the prediction module 130 uses the battery data 150 corresponding to the early time sequency data as training data for each model in the ensemble of models and the late time sequency data as supervising signals to train each model in the ensemble of models. In one approach, early time sequency data includes data that lies earlier on the SOH history curve or that is at least earlier than the late time sequency data. Similarly, in one approach, late time sequency data includes data that lies later on the SOH history curve or that is at least later than the early time sequency data. For example, referring now to FIG. 4B, suppose the historical SOH data 190 includes 6 time points t₁, t₂, t₃, t₄, t₅, and t₆. Early time sequency data can be the historical SOH data 190 at time points t₁, t₂, and/or t₃, while late time sequency data can be the historical SOH data 190 at time points t₄, t₅, and/or t₆. However, if the late time sequency data is characterized as the historical SOH data 190 at t₆, data at t₅ can be considered early time sequency data. Likewise, if the early time sequency data is characterized as the historical SOH data 190 at t₁, data at t₂ can be considered late time sequency data.

At 450, as mentioned above, the prediction module 130 uses the battery data 150 corresponding to the early time sequency data as training data for each model in the ensemble and the late time sequency SOH data as supervising signals to train each model in the ensemble. In one approach, training each model in the ensemble includes providing input data, which includes, for example, the battery data 150 corresponding to the early time sequency data, and executing each model to train each model to estimate a SOH for each battery. Training each model also includes, in one approach, receiving output data, which includes, for example, estimated SOH values for each battery, and comparing the output data to ground truth data to generate a loss value. In one approach, the ground truth data is the output 350 of the estimation model, and the prediction module uses the loss value to backpropagate the loss through the estimation model to update each iteration of each model.

In one approach, the prediction module 130 trains each model in the ensemble differently using different characterizations of the time sequency data. For example, if the SOH at t₆ is to be predicted, various combinations of the battery data 150 of t₁, t₂, t₃, t₄, and t₅ and the historical SOH data 190 can be used to train each model. For example, the prediction module 130 can train a first model using battery data 150 from t₁ and t₂ as training data and historical SOH data 190 from t₆ as the supervising signal. In another example, the prediction module 130 can train a second model using battery data 150 from t₂ and t₃ as training data and historical SOH data 190 from t₆ as the supervising signal. In yet another example, the prediction module 130 can train a third model using battery data 150 from t₁ and t₄ as training data and historical SOH data 190 from t₆ as the supervising signal. It should be understood that the aforementioned characterizations of early time sequency data and late time sequency data are merely a few examples and that other characterizations are possible as well. In some instances, training each model in the ensemble of models differently is beneficial because the best model for a future SOH prediction of new battery may depend on various factors, including the time length of the new battery data 180 and the time to the future SOH prediction. For example, as described in further detail below, use of the same model to predict a future SOH for a battery having a two-year driving history and a battery having a four-year driving history may result in different future SOH predictions having different prediction accuracies.

In one embodiment, each model in the ensemble of models is the same type of model. For example, in the embodiments described herein, each model is a Long Short-Term Memory (LSTM) algorithm. However, it should be understood that each model can be another type of model, for example, a LASSO regression, an Artificial Neural Network (ANN), a reinforcement learning model, a deep learning model, a support vector machine, a logistic regression, a linear regression, a random forest, etc. While each model is described herein as being the same type of model, it should be understood that in other instances, two or more of the models may be different types of models. Moreover, while each model in the ensemble of models is described herein as a supervised machine-learning model, it should be understood that in one or more other approaches, one or more of the models can be an unsupervised machine-learning model or a reinforced machine-learning model.

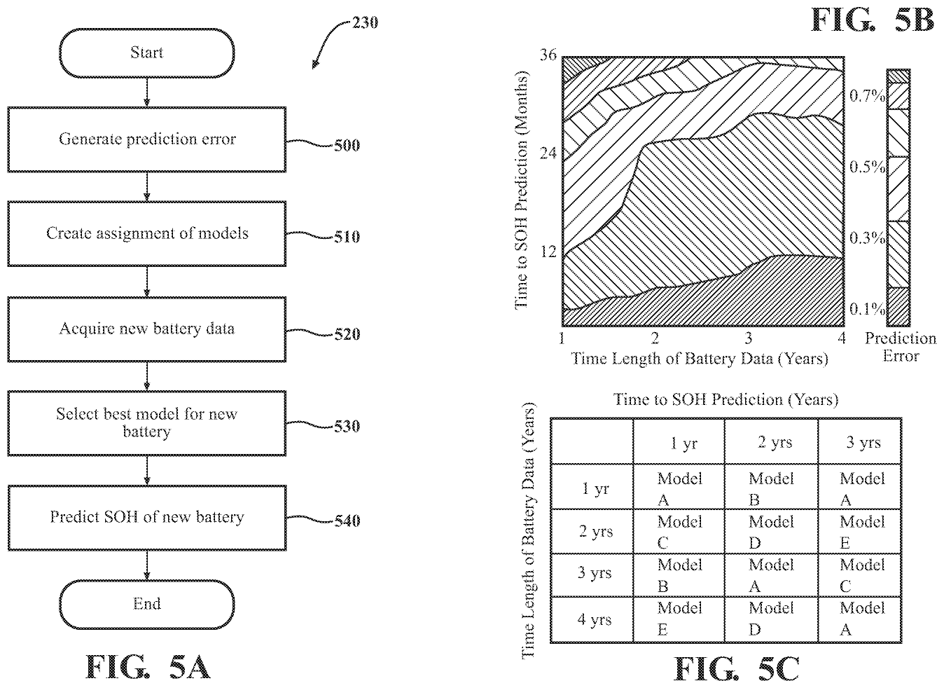

Turning now to FIGS. 5A-5C, examples of various details of the function described at block 230 are illustrated. FIG. 5A illustrates an example flowchart of a method 230 for predicting the future SOH of a new battery. At 500, the prediction module 130 generates a prediction accuracy for each model in the ensemble of models. As used herein, in one or more instances, the prediction accuracy is defined as the difference between a predicted SOH of a battery and the output 350 of the estimation model (in other words, the output estimated SOH) for that battery as a function of the time to the future SOH prediction and the time from the production of the battery. In one approach, the prediction module 130 generates the prediction accuracy by predicting the SOH at a later time sequency data point based on the battery data 150 corresponding to the early time sequency data and comparing the SOH prediction to the output 350 at the later time sequency data point. For example, to generate the prediction accuracy for one of the models in the ensemble, the prediction module 130 predicts the SOH at t₆ using the battery data 150 at t₁, t₂, t₃, t₄, and t₅ as the input to the model and compares the prediction to the output 350 at t₆. FIG. 5B shows an example of a graph of prediction accuracy as a function of the time to the SOH prediction in months and the time length of the battery data in years. In the example shown in FIG. 5B, a greater accuracy is achieved for a longer time from production and a shorter time to forecast.

In some instances, the prediction accuracy for each model will vary based on the time to the SOH prediction and the time length of the battery data (prediction criteria). Accordingly, it is advantageous to determine which model in the ensemble will provide the most accurate SOH prediction for a new battery. Thus, at 510, using the prediction accuracy for each model, the SOH prediction module 130 creates an assignment of each model to the prediction criteria. FIG. 5C illustrates example model assignments based on example prediction criteria. As shown, example battery data time lengths include 1 year, 2 years, 3 years, and 4 years, however, it should be understood that in other examples, the example battery data time lengths are other time lengths. As shown, example times to future SOH predictions are 1 year, 2 years, and 3 years, however, it should be understood that in other examples, the time to future SOH predictions are other time lengths. FIG. 5C thus illustrates an example of the assigned model for the prediction criteria.

In the example shown in FIG. 5C, the ensemble of models includes five models including a first model A, a second model B, a third model C, a fourth model D, and a fifth model E. In the example shown, the prediction module 130 has assigned model A as the best model for a 1-year future SOH prediction of a new battery having a 1-year battery data time length, a 3-year future SOH prediction of a new battery having a 1-year battery data time length, a 2-year future SOH prediction for a new battery having a 3-year battery data time length, and a 3-year future SOH prediction for a new battery having a 4-year battery data time length. Additionally, in the example shown, the prediction module 130 has assigned model B as the best model for a 2-year future SOH prediction of a new battery having a 1-year battery data time length and a 1-year future SOH prediction of a new battery having a 3-year battery data time length. Additionally, in the example shown, the prediction module 130 has assigned model C as the best model for a 1-year future SOH prediction of a new battery having a 2-year battery data time length and a 3-year future SOH prediction of a new battery having a 3-year battery data time length. Moreover, in the example shown, the prediction module has assigned model D as the best model for a 2-year future SOH prediction of a new battery having a 2-year battery data time length and a 2-year future SOH prediction of a new battery having a 4-year battery data time length. Finally, in the example shown, the prediction module 130 has assigned model E as the best model for a 3-year future SOH prediction of a new battery having a 2-year battery data time length and a 1-year future SOH prediction of a new battery having a 4-year battery data time length. It should be understood that the aforementioned assignments are merely examples and that other assignments may be used.

It should be understood that the actions taken at 500 and 510, generating the prediction error and creating an assignment of models, are, in one approach, prior functions to the actions taken at 520, 530, 540, and other subsequent steps of the method 230. More specifically, in one approach, the actions taken at 500 and 510 pre-configure the prediction module 130 so that the prediction module 130 can iteratively repeat the actions taken at 520, 530, 540, and other subsequent steps of the method 230.

At 520, the prediction module 130 acquires the new battery data 180, as described above. In one approach, the prediction module 130 receives the new battery data 180 through active acquisition (i.e., controlling a device to acquire the new battery data 180). For example, the prediction module 130 controls the processor 110 to acquire the new battery data 180 from the data store 140. In another approach, the prediction module 130 acquires the new battery data 180 through communication of the new battery data 180 via a data communication link. For example, the processor 110 initiates communication of the new battery data 180 from the data store 140 to the prediction module 130.

At 530, based on the above-described assignment, the prediction module 130 identifies a selected model for a future SOH prediction of the new battery. For example, if the new battery data 180 has a time length of 3 years and the processor 110 has instructed the prediction module 130 to predict the future SOH of the new battery in 2 years, the prediction module 130 may identify model A as the selected model. Thus, the prediction module 130 considers attributes of the battery data from which the module 130 selects a particular model to perform the prediction.

At 540, the prediction module 130 uses the new battery data 180 as the input to the selected model to generate a future SOH prediction for the new battery. For example, if the selected model is model A, the prediction module 130 inputs the new battery data 180 into model A to generate the future SOH prediction. Thus, the prediction module 130 is able to apply a model that provides the most accurate result, thereby improving predictions of SOH. In some arrangements, the new battery data 180 includes data for the time points mentioned above, for example, data at time points t₁, t₂, t₃, t₄, t₅, and t₆. In some instances, the new battery data 180 that is input to the model to generate a future SOH prediction corresponds to data at two or more of the time points. For example, the prediction module 130 can use the new battery data 180 at t₁ and t₃ to predict the future SOH. In another example, the prediction module 130 can use the new battery data 180 at t₂ and t₄ to predict the future SOH. Other combinations of the new battery data 180 are also possible to predict the future SOH.

The arrangements described herein have the benefit of providing systems and methods for accurately predicting a future SOH of a vehicle battery with a limited need for expensive, time-consuming lab measurements. The arrangements described herein also have the benefit of treating the vehicle battery individually and independently of other vehicle batteries to avoid error caused by averaging the behavior of a group of batteries for the purpose of a future SOH prediction. Finally, the arrangements described herein have the benefit of considering the environmental effects on the battery in the future SOH prediction.

Detailed embodiments are disclosed herein. However, it is to be understood that the disclosed embodiments are intended only as examples. Therefore, specific structural and functional details disclosed herein are not to be interpreted as limiting but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-5C, but the embodiments are not limited to the illustrated structure or application. The flowcharts and block diagrams in the figures illustrate the architecture, functionality, and operation of possible implementations of systems, methods, and computer program products according to various embodiments. In this regard, each block in the flow charts or block diagrams may represent a module, segment, or portion of code, which comprises one or more executable instructions for implementing the specified logical function(s). It should also be noted that, in some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved.

The systems, components, and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein. The systems, components, and/or processes also can be embedded in a computer-readable storage, such as a computer program product or other data programs storage device, readable by a machine, tangibly embodying a program of instructions executable by the machine to perform methods and processes described herein. The aforementioned elements can also be embedded in an application product that comprises all the features enabling the implementation of the methods described herein and which, when loaded in a processing system, is able to carry out the methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or another combination of the foregoing. More specific examples (a non-exhaustive list) of the computer-readable storage medium would include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or another combination of the foregoing.

In the context of this document, a computer-readable storage medium may be any tangible medium that can contain or store a program or use by or in connection with an instruction execution system, apparatus, or device. Generally, “module,” as used herein, includes routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another electronic storage medium. In still further aspects, a module as envisioned by the present disclosure is implemented as an application-specific integrated circuit (ASIC), a hardware component of a system on a chip (SoC), as a programmable logic array (PLA), or as another hardware component that is embedded with a defined configuration set (e.g., instructions) for performing the disclosed functions. The terms “operatively connected” and “communicatively coupled.” as used throughout this description, can include direct or indirect connections, including connections without direct physical contact.

Program code embodied on a computer-readable medium may be transmitted using any appropriate medium, including but not limited to wireless, wireline, optical fiber, cable, RF, etc., or another combination of the foregoing. Computer program code for carrying out operations for aspects of the present arrangements may be written in any combination of one or more programming languages, including an object-oriented programming language such as Java™, Smalltalk, C++, or the like and conventional programming languages, such as the “C” programming language or similar programming languages. The program code may execute entirely on the user's computer, partly on the user's computer, as a standalone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another.” as used herein, is defined as at least a second or more. The terms “including” and/or “having.” as used herein, are defined as comprising (i.e., open language). The phrase “at least one of . . . and . . . ” as used herein, refers to and encompasses any and all possible combinations of one or more of the associated listed items. As an example, the phrase “at least one of A, B, and C” includes A only, B only, C only, or any combination thereof (e.g., AB, AC, BC, OR ABC).

Aspects herein can be embodied in other forms without departing from the spirit or essential attributes thereof. Accordingly, reference should be made to the following claims, rather than to the foregoing specification, as indicating the scope thereof.

What is claimed is:

1. A system, comprising:
a memory communicably coupled to a processor and storing instructions that, when executed by the processor, cause the processor to:
acquire battery data of a battery for which a future state-of-health (SOH) is to be predicted;
identify a selected model from an ensemble of models according to at least a time to the future SOH and a time length of the battery data; and
predict the future SOH using the battery data as an input to the selected model.

2. The system of claim 1, wherein the instructions further cause the processor to train an estimation model to predict current state-of-health (SOH) values of batteries, wherein instructions cause the processor to train the estimation model by using current values of battery data of the batteries as training data for the estimation model and using lab-measured SOH values of the batteries as a supervising signal for the estimation model to generate a loss value of the estimation model and update the estimation model.

3. The system of claim 2, wherein the instructions further cause the processor to preprocess the current battery data before use as the training data for the estimation model by at least one of: filtering out relevant battery features and applying empirical equations related to the physics of the batteries to the current values of the battery data.

4. The system of claim 1, wherein the instructions further cause the processor to:
apply an estimation model configured to predict current SOH values of batteries to battery data of the batteries to generate historical SOH data; and
construct a SOH history curve using the SOH data.

5. The system of claim 4, wherein the instructions further cause the processor to characterize the historical SOH data as early time sequency data and late time sequency data relative to the SOH history curve, wherein the early time sequency data includes data lying earlier on the SOH history curve or at least before the late time sequency data, and wherein the late time sequency data includes data lying later on the SOH history curve or at least before the early time sequency data.

6. The system of claim 5, wherein the instructions further cause the processor to use battery data corresponding to the early time sequency data and the late time sequency SOH data to train each model in the ensemble of models, wherein the early time sequency data and the late time sequency data for each model are located at different time points of the SOH history curve.

7. The system of claim 1, wherein the instructions further cause the processor to:
generate SOH predictions for each model in the ensemble of models using historical battery data as an input to each model;
calculate a SOH prediction error for each model by comparing the SOH prediction to estimated SOH values; and
create an assignment of each model to future SOH prediction criteria, wherein the criteria include the time to the future SOH and the time length of the battery data, wherein the selected model is chosen based on the assignment.

8. A non-transitory computer-readable medium including instructions that, when executed by one or more processors, cause the one or more processors to:
acquire historical battery data of a battery for which a future state-of-health (SOH) is to be predicted;
identify a selected model from an ensemble of models according to at least a time to the future SOH and a time length of the battery data; and
predict the future SOH using the historical battery data as an input to the selected model.

9. The non-transitory computer-readable medium of claim 8, wherein the instructions further cause the processor to train an estimation model to predict current state-of-health (SOH) values of batteries, wherein instructions cause the processor to train the estimation model by using current values of battery data of the batteries as training data for the estimation model and using lab-measured SOH values of the batteries as a supervising signal for the estimation model to generate a loss value of the estimation model and update the estimation model.

10. The non-transitory computer-readable medium of claim 9, wherein the instructions further cause the processor to preprocess the current battery data before use as the training data for the estimation model by at least one of: filtering out relevant battery features and applying empirical equations related to the physics of the batteries to the current values of the battery data.

11. The non-transitory computer-readable medium of claim 8, wherein the instructions further cause the processor to:
Apply an estimation model configured to predict current SOH values of batteries to historical battery data of the batteries to generate SOH data; and
construct a SOH history curve using the SOH data.

12. The non-transitory computer-readable medium of claim 11, wherein the instructions further cause the processor to characterize the historical SOH data as early time sequency data and late time sequency data relative to the SOH history curve, wherein the early time sequency data includes data lying earlier on the SOH history curve or at least before the late time sequency data, and wherein the late time sequency data includes data lying later on the SOH history curve or at least before the early time sequency data.

13. The non-transitory computer-readable medium of claim 12, wherein the instructions further cause the processor to use battery data corresponding to the early time sequency data and the late time sequency SOH data to train each model in the ensemble of models, wherein the early time sequency data and the late time sequency data for each model are located at different time points of the SOH history curve.

14. The non-transitory computer-readable medium of claim 8, wherein the instructions further cause the processor to:
generate SOH predictions for each model in the ensemble of models using historical values of battery data as an input to each model;
calculate a SOH prediction error for each model by comparing the SOH prediction to estimated SOH values; and
create an assignment of each model to future SOH prediction criteria, wherein the criteria include the time to the future SOH and the time length of the battery data, wherein the selected model is chosen based on the assignment.

15. A method, comprising:
acquiring battery data of a battery for which a future state-of-health (SOH) is to be predicted;
identifying a selected model from an ensemble of models according to at least a time to the future SOH and a time length of the battery data; and
predicting the future SOH using the historical battery data as an input to the selected model.

16. The method of claim 15, further comprising:
training an estimation model to predict current state-of-health (SOH) values of batteries, wherein training the estimation model includes:
using current values of battery data of the batteries as training data for the estimation model; and
using lab-measured SOH values of the batteries as a supervising signal for the estimation model to generate a loss value of the estimation model and update the estimation model.

17. The method of claim 16, further comprising preprocessing the current battery data before use as the training data for the estimation model by at least one of: filtering out relevant battery features and applying empirical equations related to the physics of the batteries to the current values of the battery data.

18. The method of claim 15, further comprising:
applying an estimation model configured to predict current SOH values of batteries to historical battery data of the batteries to generate SOH data; and
constructing a SOH history curve using the SOH data.

19. The method of claim 18, further comprising:
characterizing the historical SOH data as early time sequency data and late time sequency data relative to the SOH history curve, wherein the early time sequency data includes data lying earlier on the SOH history curve or at least before the late time sequency data, and wherein the late time sequency data includes data lying later on the SOH history curve or at least before the early time sequency data; and
using battery data corresponding to the early time sequency data and the late time sequency SOH data to train each model in the ensemble of models, wherein the early time sequency data and the late time sequency data for each model are located at different time points of the SOH history curve.

20. The method of claim 15, further comprising:
generating SOH predictions for each model in the ensemble of models using historical values of battery data as an input to each model;
calculating a SOH prediction error for each model by comparing the SOH prediction to estimated SOH values; and
creating an assignment of each model to future SOH prediction criteria, wherein the criteria include the time to the future SOH and the time length of the battery data, wherein the selected model is chosen based on the assignment.
